(19) United States
(12) Patent Application Publication
(10) Pub. No.: US 2024/0290594 A1
(43) Pub. Date: Aug. 29, 2024

(54) METHOD FOR EVALUATING THERMIONIC ELECTRON EMITTER IN SITU

(71) Applicants: NuFlare Technology, Inc., Kanagawa (JP); NuFlare Technology America, Inc., Sunnyvale, CA (US)

(72) Inventor: Victor Katsap, Hopewell Junction, NY (US)

(73) Assignees: NuFlare Technology, Inc., Kanagawa (JP); NuFlare Technology America, Inc., Sunnyvale, CA (US)

(21) Appl. No.: 18/176,195

(22) Filed: Feb. 28, 2023

(51) Int. Cl. H01J 45/00; H01J 37/06; H01J 37/22; H01J 37/24

(52) U.S. Cl. CPC H01J 45/00; H01J 37/06; H01J 37/22; H01J 37/24

(57) ABSTRACT

A method of assessing thermionic electron emitter quality, comprising heating a thermionic electron emitter to an emission temperature thereby causing the emitter to emit electrons, forming the electrons emitted by the emitter into an electron beam, directing the electron beam to an image detector thereby forming an image corresponding to electron emission from a surface of the emitter, and detecting a presence or absence in the image of a pair of intersecting bright band features, each band feature being formed from two parallel lines, the band features corresponding to crystal lattice planes of the emitter. The presence of one pair of intersecting bright band features indicates a single-crystal emitter. The absence of a pair of intersecting band features indicates an amorphous or contaminated emitter. The presence of more than a single pair of intersecting bright band features indicates a polycrystalline emitter. The method is particularly useful for rare-earth hexaboride emitters.

### BACKGROUND

### Field

This disclosure generally relates to a method for evaluating the quality of a thermionic electron emitter of the type often used in electron microscopes and electron beam lithography tools.

### Description of the Related Art

The scanning electron microscope (SEM), transmission electron microscope (TEM), and electron beam lithography tool each require an electron gun with electron emission source, which generates an electron beam used to strike a target material. A wide variety of electron guns are available, utilizing different materials and techniques for producing an electron beam. Typically, the electron gun may be in the category of FEG, or field emission gun, using thermal field-effect emitters, which use a high-strength electric field to reduce the work function of a heated electron emitter, or in the category of thermionic emitters, which use high-temperature to facilitate electron emission.

Thermionic sources typically contain a tip made from crystalline (typically single-crystal) electron emissive material. The most common electron emissive material used in thermionic sources is Lanthanum hexaboride (LaB₆), but cerium hexaboride (CeB₆) and mixed lanthanum cerium hexaboride ((La,Ce)B₆) are also frequently used. Said crystal(s) typically have (100) orientation, since (100) crystalline plane provides 4-fold symmetry and exhibits the lowest work function. The electron emissive material is mounted at the tip of a heater, typically a carbon rod connected at the tip and split into to “legs” at an opposite end. The legs are connected to a voltage source and current can flow up one leg, through the connected tip near the electron emissive material, then down the other leg. This current causes resistive heating including of the tip of the heater. The heat is transferred to the electron emissive material, facilitating thermionic emission. A high-quality thermionic emitter, such as a LaB₆ emitter, exhibits a high brightness (current density), a low energy spread of emitted electrons (leading to, for example, a higher imaging resolution), a low evaporation rate (leading to long usage lifetime), a lower work function (leading to a lower operating temperature and longer service life), and a stable emission.

To achieve desired emission properties, the LaB₆ emitter should be single-crystal, free of defects, and have a smooth, crystallographically oriented surface that is free of contaminants. While typically grown as a single crystal, LaB₆ emitters used in electron microscopes and electron beam lithography tools are often ground, shaped, and polished to produce the desirable emission surface. Characterization of this emission surface is typically performed during the formation or assembly of the emission cathode. The typical characterization, however, does not ensure that a high-quality emitter is formed nor that the emitter that was formed as high-quality has remained high-quality after, for example, shipping and installation. Damage may occur during packaging, transit, or installation that can reduce the quality of the emitter. One of the most common problems is contamination of the emitter surface. One common contaminant which may be present on LaB₆ emitter surfaces is lanthanum oxide (La₂O₃). LaB₆ is hygroscopic, readily absorbing moisture from ambient atmosphere to form lanthanum oxide or lanthanum hydroxide (La(OH)₃), which is converted to lanthanum oxide upon heating or use in forming an electron beam.

Polycrystalline or amorphous electron emitters can exhibit higher work functions and therefore lower brightness compared with single-crystal electron emitters. Further, the use of polycrystalline or amorphous electron emitters can result in an asymmetric or non-uniform electron beam. Such an asymmetric or non-uniform electron beam is more difficult to shape, direct, and control properly. Additionally, the asymmetry or non-uniformity can result in a loss of resolution. These effects are disadvantageous for imaging, lithography, and other applications of electron beam tools. Polycrystalline emitters can also have different regions that have slightly different work functions. The difference in work functions can lead to a greater spread in emitted electron energies, resulting in greater imaging aberration. Such aberration can be difficult or impossible to correct, resulting in disadvantageous outcomes such as loss of resolution.

Surface contaminants can dramatically decrease the performance of the electron emitter. For example, organic contaminants typically decrease the brightness of the electron emitter. Further, a non-uniform distribution of contaminants can compromise the uniformity of the resulting electron beam. Both of these effects are disadvantageous for use in electron microscopes, electron beam lithography tools, and other similar devices. Other contaminants can increase certain performance parameters while decreasing others. Lanthanum oxide, for example, has a significantly lower work function and therefore brightness compared to LaB₆. Lanthanum oxide, however, also has a significantly higher evaporation rate, dramatically decreasing the lifetime of the electron emitter, and its distribution over the LaB₆ emission surface is uneven, causing nonuniform emission The rapid evaporation of surface lanthanum oxide can also negatively affect performance by causing repeated change of operating parameters as the properties of the resulting electron beam are not stable.

Common methods of ensuring a single-crystal, surface orientation, lack of contamination, and the like require either dedicated instruments or are not compatible with characterizing the electron emitter while installed in the electron microscope or other tool. Thus, the quality of an electron emitter cannot be assessed quickly and easily while in the tool in which it is used. The electron emitter must either be characterized before installation, which presents time and opportunity for accidental degradation or contamination to occur, or the electron emitter must be removed from the electron microscope or other instrument or tool for characterization, leading to increased cost and disadvantageous downtime. Further, because the electron emitter must then be reinstalled, the electron emitter may become damaged or contaminated during removal, characterization, or reinstallation.

Accordingly, it is one object of the present disclosure to provide a method of assessing the quality of an electron emitter in situ. That is, the quality of the electron emitter can be assessed while in an electron microscope, electron beam lithography tool, or other such instrument or tool.

### SUMMARY

Embodiments of the present disclosure describe a method of assessing thermionic electron emitter quality. The method allows such quality assessment without removing the thermionic electron emitter from an electron microscope, an electron beam lithography tool, or other suitable such device in which the thermionic electron emitter is installed.

A first embodiment describes a method of assessing thermionic electron emitter quality, the method comprising heating a thermionic electron emitter to an emission temperature thereby causing the thermionic electron emitter to emit electrons, forming the electrons emitted by the thermionic electron emitter into an electron beam, directing the electron beam to an image detector thereby forming an image corresponding to electron emission from a surface of the thermionic electron emitter, and detecting a presence or absence in the image of a pair of intersecting band features, each band feature being formed from two parallel lines, the band features corresponding to crystal lattice planes of the thermionic electron emitter, wherein the presence of the pair of intersecting band features indicates a single-crystal thermionic electron emitter, and wherein the absence of the pair of intersecting band features indicates an amorphous or contaminated thermionic emitter and the presence of more than a single pair of intersecting band features indicates a polycrystalline thermionic electron emitter.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIGS. 1A-1B depict conventional thermionic electron emission cathode assemblies in which a thermionic electron emitter is mounted to the end of a carbon heater rod (FIG. 1A) or on a wire-type heater (FIG. 1B).

FIG. 2 is a flowchart depicting the method of assessing thermionic electron emitter quality, according to an exemplary embodiment of the present disclosure.

FIG. 3 shows a schematic depiction of electron optics (apertures, electromagnetic lenses, and coils) used for forming the electrons emitted by a thermionic emitter into an electron beam and for shaping and directing the electron beam.

FIG. 4A shows a representation of the trajectories of electrons emitted from a conical thermionic electron emitter.

FIG. 4B shows a representation of the components of a typical electron microscope or electron beam lithography tool and the effect of each component on the electron beam.

FIG. 5A is an emission image of a high-quality lanthanum hexaboride thermionic emitter having a (100) orientation, according to an exemplary embodiment of the present disclosure.

FIG. 5B is an annotated emission image of a high-quality lanthanum hexaboride thermionic emitter having a (100) orientation in which the pair of intersecting band features are straight, intersect at an angle of approximately 90 degrees, and correspond to the (010) and (001) lattice planes, according to an exemplary embodiment of the present disclosure.

FIG. 5C is an emission image of a high-quality lanthanum hexaboride thermionic emitter having a (310) orientation in which the pair of intersecting band features are curved and intersect at an angle that is not 90 degrees, according to an exemplary embodiment of the present disclosure.

FIG. 6A is an emission image of a low-quality lanthanum hexaboride thermionic emitter resulting from improper crystal growth, according to an exemplary embodiment of the present disclosure. The shape and pattern of features in the emission image is thought to be the result of the growth method imposing undue stress in the growing crystal.

FIGS. 6B-6C are scanning electron microscope images (FIG. 6A) and a corresponding emission image (FIG. 6B) of a low-quality lanthanum hexaboride thermionic emitter that is polycrystalline, according to an exemplary embodiment of the present disclosure.

FIG. 6D is an emission image of a low-quality lanthanum cerium hexaboride (La_{0.35}Ce_{0.65}B₆) thermionic emitter that is polycrystalline, according to an exemplary embodiment of the present disclosure. Other characterization had indicated that the thermionic emitter was a single crystal, but the emission image shows the thermionic emitter is actually polycrystalline.

### DETAILED DESCRIPTION

The method of the present disclosure describes forming an image of the thermionic electron emitter of a cathode to evaluate the quality of the thermionic electron emitter.

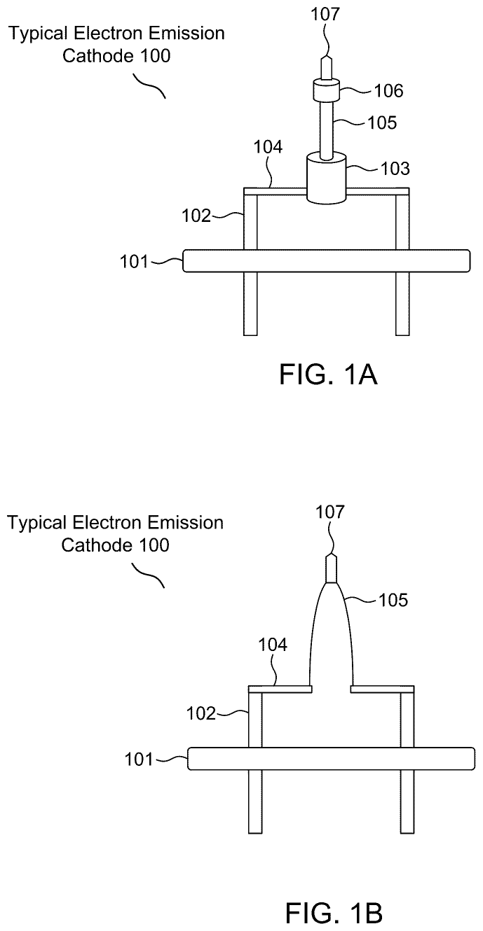

FIGS. 1A-1B show depictions of typical electron emission cathodes that are compatible with the method of the present disclosure. As shown in the figures, a typical electron emission cathode 100 comprises a base 101 constructed of a suitable dielectric material. Preferably, the base 101 is constructed of an insulating material that is capable of withstanding the high-temperatures encountered during operation of a thermionic electron emission cathode 100, such as a ceramic or glass. The base 101 may serve as a convenient support for allowing or facilitating connection or installation of the cathode 100 into a suitable device, such as an electron microscope or electron beam lithography tool.

A pair of base pins 102 extend from beyond a bottom face of the base 101, the bottom face being an opposite face to a face on which other components described below are connected, through the base to above an upper face of the base 101, the face on which other components described below are connected. The base pins 102 are typically formed from a conductive material to provide an electrical connection from a power supply or voltage source to certain portions of the cathode that require electricity, such as the heater 105. Certain thermionic electron emission cathodes 100 such as that depicted in FIG. 1A comprise a sub-base 103. Preferably, the sub-base 103 is constructed of an insulating material that is capable of withstanding the high-temperatures encountered during operation of a thermionic electron emission cathode 100, such as a ceramic or glass. Typically, the sub-base 103 is connected to a suitable portion of the base 101, such as the base pins 102, by a pair of mounting straps 104. These mounting straps 104 are preferably formed from a conductive material or contain a conductive material that forms an electrical connection between a power supply or voltage source and the heater 105. In cathodes which do not have a sub-base, such as the cathode depicted in FIG. 1B, the mounting straps can connect directly to the heater 105. The heater 105 can be any suitable type of heater, for example a resistive heater.

In FIG. 1A, for example, the thermionic cathode is shown with a rod heater 105 formed from a split carbon rod. The rod is divided into two “legs” that are connected at the tip. The electron emission cathode includes an electron emitter 107. The electron emitter 107 is mounted or disposed on the heater at or near the tip of the heater 105. The electron emitter 107 can be connected to the heater 105 through the use of a suitable connector 106. In FIG. 1B, the heater 105 is shown as a wire-type heater.

The specific construction and components present in the electron emission cathodes 100 depicted in FIGS. 1A-1B are not intended to be limiting on the method described herein. Such electron emission cathodes are provided and described for exemplary purposes. The method described herein is compatible with a wide variety of electron emission cathodes, which may vary based on the construction and/or components present.

The electron emission cathode includes an electron emitter. In general, the electron emitter may contain or be formed from any suitable electron emissive material. Preferably, the electron emissive material is capable of withstanding high-temperature (for example, has a high-melting point), has low evaporation rate, and has a low work function. Examples of suitable materials that may form or be included in the electron emitter include, but are not limited to tungsten, thoriated tungsten, barium oxide, lanthanum hexaboride, and cerium hexaboride. Of particular relevance to the present disclosure are electron emitters formed from rare-earth hexaboride (MB₆, where M is a rare-earth element). Typically, the rare-earth hexaboride is lanthanum hexaboride LaB₆, cerium hexaboride CeB₆, or a mixed lanthanum cerium hexaboride (La,Ce)B₆. The mixed lanthanum cerium hexaboride may have a chemical formula LaₓCe₁₋ₓB₆, where 0.01≤x≤0.99. Preferably, the rare-earth hexaboride is crystalline, more preferably single crystal. In preferred embodiments, the single crystal rare-earth hexaboride has a (100)-oriented emission surface.

The LaB₆ or other suitable material (such as cerium hexaboride) may be in the form of a crystal body. The crystal body may be of any suitable, convenient, and useful shape. In some embodiments, the crystal body is cylindrical with a circular cross-section and a diameter in a range of about 20 μm to about 800 μm. Alternatively, the shape may be a rectangular solid with a rectangular cross section, in which a diagonal of the rectangle is in a range of about 400 μm to about 1,600 μm. The choice of crystal body shape and size will generally depend on the particular cathode application (including but not limited to SEM, TEM, lithography tool, probe, free electron laser, electron and ion guns, etc.) and the type of heater employed. For example, a Vogel-mount heater typically requires a rectangular crystal body shape (see, e.g., Vogel, S. F. Rev. Sci. Instr., 41, 585, 1970) and a coaxial heater (e.g., a carbon rod heater or a ring-mount heater) typically requires a cylindrical crystal body shape (see, e.g., Hohn, F. et al., J. AppL. Phys., 53(3), March 1982).

The electron emitter may be of any suitable shape. In some embodiments, the electron emitter is generally cylindrical or substantially cylindrical in shape, having straight sides, which may be coated with a carbon coating. A length of the emitter body generally ranges from about 0.50 mm to about 3 mm. In some embodiments, the electron emitter has a cross-section that is generally round or rectangular, with a diameter (or width, if a rectangle) in a range of about 20 μm to about 800 μm.

In some embodiments, an end of the electron emitter (e.g., the emitter tip) may be flat, pointed (e.g., cone-shaped or prismatic) or curved (e.g. spherical or dome-shaped). The diameter of the tip is generally in a range of about 5 μm to about 1500 μm, and preferably in a range of about 5 μm to about 1400 μm. In some embodiments, an upper section of the electron emitter, e.g., about the upper 50 μm to 200 μm of the electron emitter, may generally be conical in shape, with a cone angle in a range of about 20 degrees to about 90 degrees and is preferably in a range of about 60 degrees to about 90 degrees. In some embodiments, the cone angle is 60 degrees.

The shape and size of the electron emitter may impact cathode maximum brightness and maximum emission current available. The selection of a particular size will be based largely on the particular application of the cathode. For example, for a SEM, a high brightness but small emission current is needed, so a tip size of about 5 μm may be optimal. In lithography tools, medium brightness and high emission current are required, so a tip of 50 μm size or greater may be optimal. As the present disclosure is not limited to a specific application, there is no specific limitation on a size of the electron emitter that may be used.

As shown in FIGS. 1A-1B, the electron emitter is mounted or disposed on the heater at or near the tip. In some embodiments, the thermionic electron emitter has a substantially flat shape. There is, in general, no limitation to the size or shape of the substantially flat thermionic electron emitter. Such a substantially flat thermionic electron emitter may have any suitable cross-sectional shape, examples of which include, but are not limited to circular, elliptical, polygonal, or irregular. In some embodiments, the thermionic electron emitter has a substantially conical shape. The conical shape may have any suitable cone angle. The conical shape may have any suitable cross-sectional shape, examples of which include, but are not limited to circular, elliptical, polygonal, or irregular.

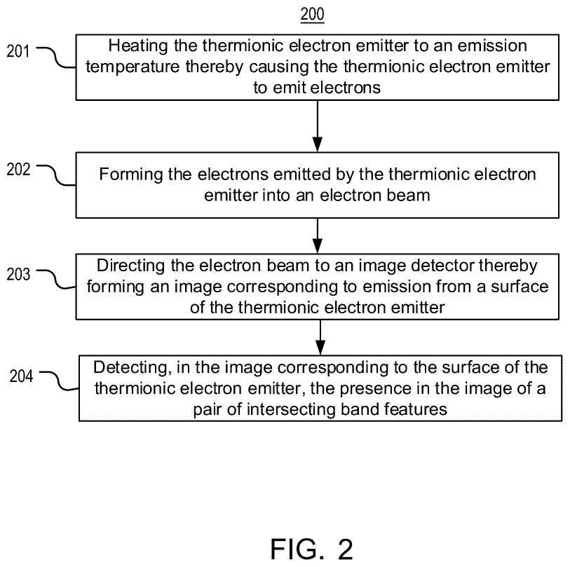

The method is summarized in the flowchart shown in FIG. 2. The method 200 of assessing thermionic electron emitter quality comprises heating 201 the thermionic electron emitter to an emission temperature thereby causing the thermionic electron emitter to emit electrons. In some embodiments, the thermionic electron emitter is at least one selected from the group consisting of lanthanum hexaboride, cerium hexaboride, and lanthanum cerium hexaboride, as described above. In preferred embodiments, the thermionic electron emitter is crystalline. In some embodiments, the method of assessing thermionic electron emitter quality is capable of determining if the thermionic electron emitter is crystalline. That is, the method is capable of distinguishing a crystalline thermionic electron emitter from a non-crystalline (amorphous) thermionic electron emitter. In more preferred embodiments, the thermionic electron emitter is a single-crystal. In some embodiments, the method of assessing thermionic electron emitter quality is able to determine if the thermionic electron emitter is a single-crystal or polycrystalline. That is, the method is able to distinguish a single-crystal thermionic electron emitter from a polycrystalline thermionic electron emitter.

In general, any suitable the thermionic electron emitter may be heated to any suitable emission temperature. In some embodiments, the emission temperature used in the method is lower than a standard operating temperature of the instrument or tool in which the thermionic electron emitter is installed. In some embodiments, the emission temperature may be lower than the standard operating temperature by 5 K to 250 K, preferably 10 K to 200 K, more preferably 15 K to 175 K, still more preferably 20 K to 150 K. Typically, electron microscopes, electron beam lithography tools, or other such instruments or tools are capable of operating in a “temperature-limited mode” or “deep temperature-limited mode” in which the emission temperature is lower than the standard operating temperature. In some embodiments, a “space charge limited mode” is used.

In some embodiments, a voltage may be applied to the thermionic electron emitter. In such embodiments, the voltage should be applied so as to keep an electric field strength at a surface of the thermionic electron emitter to a magnitude of 1 V/mm to less than 450 V/mm, preferably 2.5 V/mm to less than 425 V/mm, preferably 5 V/mm to less than 400 V/mm, preferably 7.5 V/mm to less than 375 V/mm, preferably 10 V/mm to less than 350 V//mm, preferably 12.5 V/mm to less than 325 V/mm, preferably 15 V/mm to less than 300 V/mm. This electric field strength may be advantageous for limiting field emission from the thermionic electron emitter.

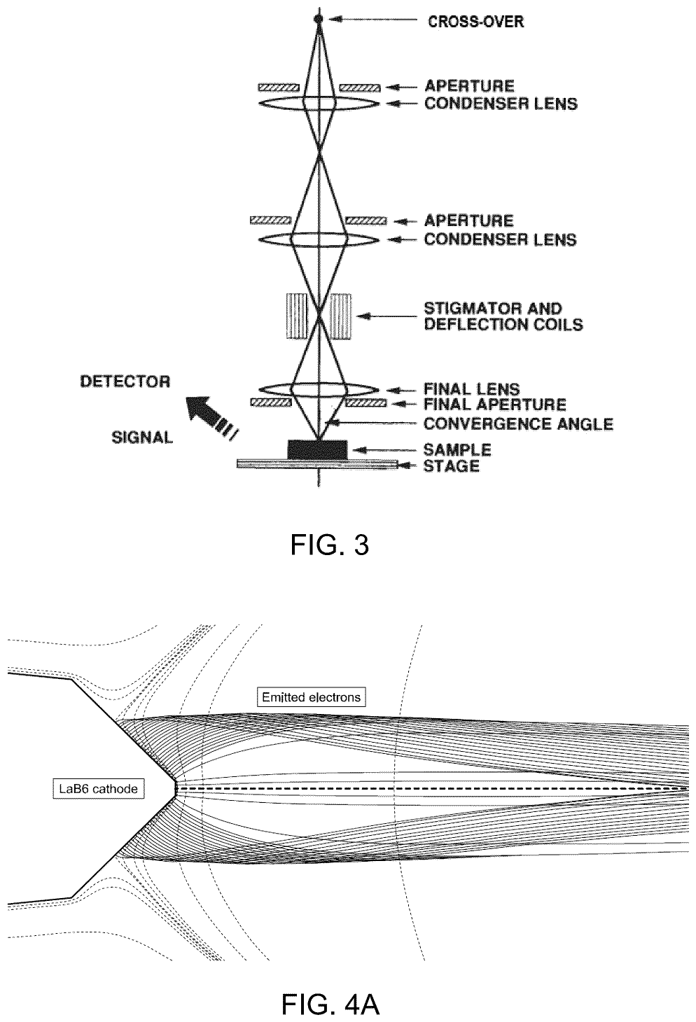

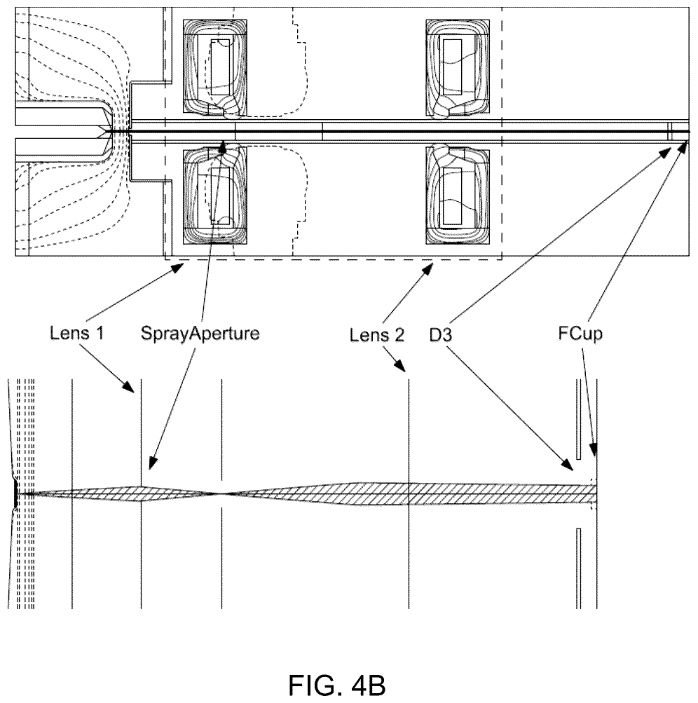

The method 200 then comprises forming 202 the electrons emitted by the thermionic electron emitter into an electron beam. Such forming 202 can involve any suitable steps, be accomplished with any suitable equipment, and be performed by any suitable technique. An example of a suitable set of equipment useful in the forming is shown in FIG. 3. An exemplary depiction of the orientation of such equipment into an electron optics column and interactions or operating of such equipment in forming the electron beam are shown in FIGS. 4A-4B.

In some embodiments, the forming 202 involves guiding the electrons emitted by the thermionic electron emitter with an electromagnetic lens. Such directing can be accomplished by methods of using electromagnetic lenses. Such guiding can involve the steering of electrons into a beam, shaping of the beam, and directing of the beam itself.

In some embodiments, the forming 202 collects at least 90%, preferably at least 92.5%, preferably at least 95%, preferably at least 97.5%, preferably at least 99% of the electrons emitted by the thermionic electron emitter into the electron beam. That is, at least 90%, preferably at least 92.5%, preferably at least 95%, preferably at least 97.5%, preferably at least 99% of the electrons emitted by the thermionic electron emitter are incorporated into the electron beam.

In preferred embodiments, the thermionic electron emitter does not have a space charge cloud around the thermionic electron emitter. A space charge cloud is typically composed of electrons emitted from other portions of the thermionic electron emitter that are not the tip. The use of a higher emission temperature (such as the standard operating temperature described above), a higher surface electric field strength, and/or a lower acceleration voltage can be associated with the formation of a space charge cloud. In some embodiments, no space charge cloud is generated during the emitting. In some embodiments, a space charge cloud is generated and is removed during the forming 302 of the emitted electrons into the electron beam. Such removal can be accomplished by any suitable steps of the forming, for example, those described above.

The method then comprises directing 203 the electron beam to an image detector thereby forming an image corresponding to emission from a surface of the thermionic electron emitter. Such an image may be known as an “emission image” or other similar term. In general, the image detector can be any suitable image detector. Examples of such image detectors include, but are not limited to fluorescent screens, charge-coupled detectors (CCDs), and scintillators.

In some embodiments, the image corresponding to emission from the surface of the thermionic electron emitter has a magnification of 1× to 16×, preferably 1.5× to 12×, preferably 2× to 10×, preferably 2.5× to 8×, preferably 3× to 6× preferably 3.5× to 5×. In some embodiments, the image corresponding to emission from the surface of the thermionic electron emitter has a resolution of 0.1 to 10 μm, preferably 0.5 to 7.5 μm, preferably 1 to 5 μm.

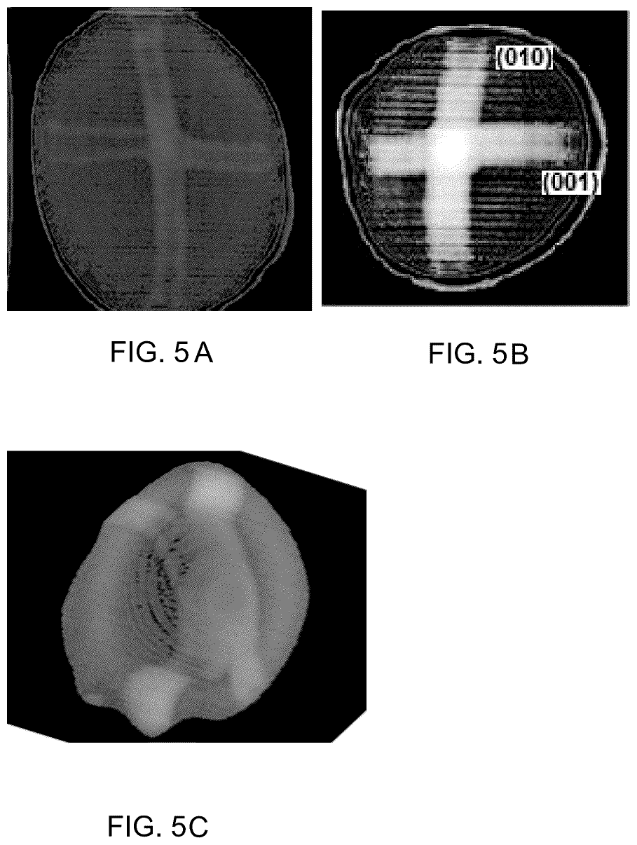

The method then comprises detecting 204, in the image corresponding to the surface of the thermionic electron emitter, the presence in the image of a pair of intersecting band features. As described below, these intersecting band features correspond to lattice planes of the thermionic electron emitter. The pair of intersecting band features may be present as bright areas in the image corresponding to the surface of the thermionic electron emitter. Examples of images corresponding to the surface of the thermionic electron emitter that exhibit the pair of intersecting band features are shown in FIGS. 5A-5C. Typically, the band features appear as bright areas compared to other portions of the image.

In general, the detecting 204 can be performed by any suitable technique and with any suitable equipment. For example, the detecting 204 may be performed by visual inspection by a user. In another example, the detecting 204 may be performed by capturing the image using photographic film which may then be analyzed. In another example, the detecting 204 may involve capturing the image using a digital image capture apparatus such as a digital camera or detector. The captured image may then be analyzed. Such analysis may involve any suitable image processing techniques. Examples of such image processing techniques include, but are not limited to, noise reduction, contrast enhancement, despeckling, filtering, convoluting, deconvoluting, aliasing, anti-aliasing, and the like. In some embodiments, the detecting is performed automatically by a suitable computer vision, machine vision, or artificial intelligence.

The presence of one pair of intersecting bright band features indicates a high-quality thermionic electron emitter. FIGS. 5A-5C show images corresponding to the surface of high-quality thermionic electron emitters. The pair of intersecting bright band features is clearly visible in each of the figures.

In some embodiments, the thermionic electron emitter is a rare-earth hexaboride having a (100) orientation. FIGS. 5A-5B correspond to (100) oriented LaB₆ emitters. In such embodiments, the intersecting band features are straight. Further information regarding the shape of the intersecting band features is provided below. In some embodiments, the intersecting band features have an intersection angle of 75 degrees to 105 degrees, preferably 80 degrees to 100 degrees, preferably 82.5 degrees to 97.5 degrees, preferably 85 degrees to 95 degrees, preferably 87.5 degrees to 92.5 degrees, preferably 89 degrees to 91 degrees, preferably 90 degrees. It is worth noting that while an ideal intersection angle for a (100)-oriented rare-earth hexaboride emitter is 90 degrees, small distortions caused by aberrations, misalignments, astigmatisms, or other imperfections in the electron optics column can cause the measured intersection angle to deviate slightly from 90 degrees. Further information regarding the intersection angle of the intersecting band features is provided below.

The presence of a single pair of intersecting band features is correlated with a preferred work function of the emitter. In the case of (100) oriented LaB₆, the preferred work function is approximately 2.60 eV.

In some embodiments, the thermionic electron emitter is a rare-earth hexaboride having a (310) orientation. FIG. 5C corresponds to a (310)-oriented LaB₆ emitter. In such embodiments, the intersecting bright band features are curved. Further information regarding the shape of the intersecting band features is provided below. In some embodiments, the intersecting band features have an intersection angle that is not 90 degrees. Further description regarding the intersection angle of the intersecting band features is provided below.

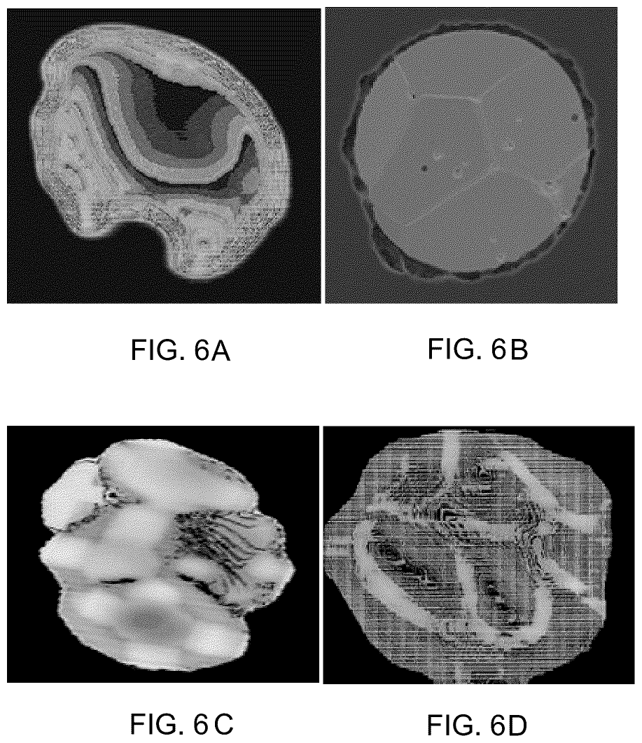

The absence of the pair of intersecting band features or the presence of more than a single pair of intersecting band features indicates a low-quality thermionic electron emitter. Images corresponding to low-quality thermionic electron emitters are shown in FIGS. 6A-6D. FIG. 6A is an emission image that corresponds to an improperly-grown LaB₆ emitter. No pair of intersecting bright band features is visible in the emission image. The emission image appears to be significantly distorted from a circular shape and has a non-circular distribution of bright and dark areas. The emitter is of low crystallinity, does not have the proper surface crystallographic orientation, and was found to have a significantly higher work function of 2.78 eV.

FIGS. 6B-6D are images corresponding to polycrystalline emitters. FIG. 6B is a scanning electron microscope (SEM) image of a polycrystalline (100)-oriented LaB₆ emitter. FIG. 6C is a corresponding emission image of the emitter shown in FIG. 6B. It is clear that each crystalline region shows its own pair of intersecting band features, however the band features are not distinctly brighter than the surrounding region, possibly indicating low crystallinity, a high concentration of defects, or a large deviation from the (100) orientation. Each of these is associated with a higher work function compared to the preferred 2.60 eV. That a pair of intersecting band features is not centered within some of the crystalline regions may indicate that those crystalline regions are slightly off the (100) orientation. FIG. 6D is an emission image corresponding to the surface of a (100)-oriented mixed lanthanum cerium hexaboride emitter having a chemical formula of (La_{0.35}Ce_{0.65}B₆). It is clear that while there are bright band features, there are a large number of such band features with multiple intersections. There appears to be a pair of intersecting band features that are straight and have an intersection angle of approximately 90 degrees as expected for (100)-oriented (La_{0.35}Ce_{0.65}B₆), but the presence of multiple pairs of intersecting band features indicates that the emitter is polycrystalline. The observation that some of the intersections of the band features are off-center in the crystalline regions and some of the intersection angles are not 90 degrees indicates that those regions may be off the (100) orientation.

Without wishing to be bound by theory, it is hypothesized that the pair of intersecting band features correspond to areas of enhanced electron emission caused by electrons being waveguided. Lattice planes that are oriented substantially perpendicular to the crystallographic orientation of the surface of the thermionic electron emitter can, under appropriate conditions, provide lower energy loss or collision-free pathways for electrons to travel through the lattice. Consider the example of (100)-oriented LaB₆. Electrons approaching and leaving the (100) LaB₆ emitting surface carry energy equal or exceeding work function, which is ˜2.60 eV, therefore these electrons' De Broglie wavelength λ is approximately λ˜ 0.76 nm. The (100) LaB₆ crystal contains 2 sets of parallel planes, which are perpendicular to the (100) lattice planes, the (010) plane and the (001) plane, both with lattice constant a˜0.416 nm (the same as the (100) plane). These parallel planes are hypothesized to act as a waveguides. For an electron with an energy near the (100) LaB₆ work function to become a guided wave, its wavelength must be λ≤2*a, and this condition is satisfied as λ˜0.76 nm is indeed smaller than 2*a=0.832 nm.

Electrons traveling through the crystal lattice to the surface of the emitter experience collisions that define crystal resistance. Collisions may deflect electrons' momentum away from an emitting surface. However, waveguided electrons should experience significantly fewer collisions, and so if an electron with energy near work function is guided toward an emitting surface, it has a higher chance of reaching the emitting surface and leaving the crystal than non-guided electron that may be collision-deflected sideways despite having enough energy to get over surface potential barrier. The preferential guidance and comparatively lower change of energy loss due to collisions of electrons traveling along the (010) and (001) planes cause a greater number of electrons to be emitted from these planes. This greater concentration results in the bright bands present in the image of the surface of the thermionic electron emitter. In the case of (100) LaB₆, the bands have an intersection angle of 90 degrees due to the (010) and (001) planes being perpendicular in the cubic lattice of LaB₆. The bands are hypothesized to be straight due to the (010) and (001) planes being mutually perpendicular to the (100) surface orientation. This is shown, for example, in FIGS. 5A-5B. It is hypothesized that only the low-index planes satisfy the waveguiding criterion of λ≤2*a, and thus are the only such planes which show this type of emission enhancement behavior.

In the case of a different crystallographic orientation, such as (310) LaB₆, the bands may be curved. Such curving may be due to applicable low-index lattice planes being oriented at an angle that is not perpendicular to the (310) plane. Additionally, applicable low-index lattice planes may not be perpendicular to each other, leading to an intersection angle that is not 90 degrees. This is shown, for example, in FIG. 5C.

Embodiments of the present disclosure may also be as set forth in the following parentheticals.

(1) A method of assessing thermionic electron emitter quality, the method comprising heating a thermionic electron emitter to an emission temperature thereby causing the thermionic electron emitter to emit electrons, forming the electrons emitted by the thermionic electron emitter into an electron beam, directing the electron beam to an image detector thereby forming an image corresponding to electron emission from a surface of the thermionic electron emitter, and detecting a presence or absence in the image of a pair of intersecting band features, each band feature being formed from two parallel lines, the band features corresponding to crystal lattice planes of the thermionic electron emitter, wherein the presence of the pair of intersecting band features indicates a single-crystal thermionic electron emitter, and wherein the absence of the pair of intersecting band features indicates an amorphous or contaminated thermionic emitter and the presence of more than a single pair of intersecting band features indicates a polycrystalline thermionic electron emitter.

(2) The method of (1), wherein the thermionic electron emitter is at least one selected from the group consisting of lanthanum hexaboride, cerium hexaboride, and lanthanum cerium hexaboride.

(3) The method of any one of (1) to (2), wherein the thermionic electron emitter does not have a space charge cloud around the thermionic electron emitter during the step of the heating.

(4) The method of any one of (1) to (3), further comprising applying a voltage to the thermionic electron emitter.

(5) The method of (4), wherein an electric field strength at the surface of the electron emitter has a magnitude from 0 V/mm to less than 450 V/mm.

(6) The method of any one of (1) to (5), wherein the forming comprises accelerating the electrons emitted by the thermionic electron emitter.

(7) The method of any one of (1) to (6), wherein the forming comprises guiding the electrons emitted by the thermionic electron emitter with at least one electromagnetic lens.

(8) The method of any one of (1) to (7), wherein the forming comprises collecting at least 90% of the electrons emitted by the thermionic electron emitter into the electron beam.

(9) The method of any one of (2) to (8), wherein the surface of the thermionic electron emitter has a (100) orientation.

(10) The method of any one of (2) to (9), wherein the intersecting band features are straight.

(11) The method of any one of (2) to (10), wherein the intersecting band features have an intersection angle of 75 to 105 degrees.

(12) The method of any one of (1) to (11), wherein the emission temperature is 1600 K to 1800 K.

(13) The method of any one of (1) to (12), wherein the image corresponding to emission from the surface of the thermionic electron emitter has a magnification of 1× to 16×.

Numerous modifications and variations of the present invention are possible in light of the above teachings. It is therefore to be understood that within the scope of the appended claims, the invention may be practiced otherwise than as specifically described herein.

1. A method of assessing thermionic electron emitter quality, the method comprising:
heating a thermionic electron emitter to an emission temperature thereby causing the thermionic electron emitter to emit electrons;
forming the electrons emitted by the thermionic electron emitter into an electron beam;
directing the electron beam to an image detector thereby forming an image corresponding to electron emission from a surface of the thermionic electron emitter; and
detecting a presence or absence in the image of a pair of intersecting band features, each band feature being formed from two parallel lines, the band features corresponding to crystal lattice planes of the thermionic electron emitter,
wherein the presence of the pair of intersecting band features indicates a single-crystal thermionic electron emitter,
wherein the absence of the pair of intersecting band features indicates an amorphous or contaminated thermionic emitter, and
wherein the presence of more than a single pair of intersecting band features indicates a polycrystalline thermionic electron emitter.

2. The method of claim 1, wherein the thermionic electron emitter is at least one selected from the group consisting of lanthanum hexaboride, cerium hexaboride, and lanthanum cerium hexaboride.

3. The method of claim 1, wherein the thermionic electron emitter does not have a space charge cloud around the thermionic electron emitter during the step of the heating.

4. The method of claim 1, further comprising applying a voltage to the thermionic electron emitter.

5. The method of claim 4, wherein an electric field strength at the surface of the electron emitter has a magnitude from 0 V/mm to less than 450 V/mm.

6. The method of claim 1, wherein the forming comprises accelerating the electrons emitted by the thermionic electron emitter.

7. The method of claim 1, wherein the forming comprises guiding the electrons emitted by the thermionic electron emitter with at least one electromagnetic lens.

8. The method of claim 1, wherein the forming comprises collecting at least 90% of the electrons emitted by the thermionic electron emitter into the electron beam.

9. The method of claim 2, wherein the surface of the thermionic electron emitter has a (100) orientation.

10. The method of claim 2, wherein the intersecting band features are straight.

11. The method of claim 2, wherein the intersecting band features have an intersection angle of 75 degrees to 105 degrees.

12. The method of claim 1, wherein the emission temperature is 1600 K to 1800 K.

13. The method of claim 1, wherein the image corresponding to emission from the surface of the thermionic electron emitter has a magnification of 1× to 16×.
